(19) United States
(12) Patent Application Publication
(10) Pub. No.: US 2023/0064442 A1
(43) Pub. Date: Mar. 2, 2023

(54) CHIP PACKAGE STRUCTURE, CHIP PACKAGE SYSTEM, AND METHOD OF FORMING A CHIP PACKAGE STRUCTURE

(71) Applicant: Infineon Technologies AG, Neubiberg (DE)

(72) Inventors: Chan Whai Augustine KAN, Singapore (SG); Martin MAYER, Nittendorf (DE); Edmund RIEDL, Wald (DE); Edward FUERGUT, Dasing (DE); Harry Walter SAX, Straubing (DE)

(73) Assignee: Infineon Technologies AG, Neubiberg (DE)

(21) Appl. No.: 17/879,900

(22) Filed: Aug. 3, 2022

(30) Foreign Application Priority Data
Aug. 18, 2021 (DE) 10 2021 121 448.3

(51) Int. Cl. H01L 23/367; H01L 23/31; H01L 23/42; H01L 23/00

(52) U.S. Cl. CPC H01L 23/3672; H01L 23/3107; H01L 23/42; H01L 24/32; H01L 24/29; H01L 24/83; H01L 2224/32225; H01L 2224/29186; H01L 2224/8349; H01L 2224/834

(57) ABSTRACT

A chip package structure is disclosed. In one example, the chip package may include a chip, an encapsulation material, and an exposed pad that is electrically conductively connected to the chip. A layer of a porous or dendrite-comprising adhesion promoter is on a surface of the exposed pad. A thermal interface material that is attached to the exposed pad by the layer.

### CROSS-REFERENCE TO RELATED APPLICATION

This Utility Patent Application claims priority to German Patent Application No. 10 2021 121 448.3, filed Aug. 18, 2021, which is incorporated herein by reference.

### TECHNICAL FIELD

Various embodiments relate generally to a chip package structure and to a method of forming a chip package structure.

### BACKGROUND

Chip packages may be coupled to a heat sink by a thermal interface material (TIM). In many cases, the thermal interface material may have a coefficient of thermal expansion (CTE) that does not match well with a CTE of exposed metals and/or polymers of the chip package. A reason for the mismatch may for example be a polymer matrix of the TIM (e.g., silicones have a very high CTE), and/or filler particles/materials that may be included in the polymer matrix, and which may amount to e.g. 85-95 wt % of the thermal interface material.

Thermomechanical stress resulting from the CTE mismatch may lead to delamination between the interfaces. Especially an adhesion of TIM materials on already cured epoxy materials that desorb waxes may be critical. The delamination may lead to a large increase in thermal resistance Rth, which may cause an overheating of the device. Furthermore, in some cases the delamination may lead to electrical failures. To be creepage conform, some devices (e.g discrete power package, power module, intelligent power module) are not allowed to delaminate.

For keeping a chip at a reasonable operating temperature even in a high power module, advanced thermal transmission may be required, but at the same time, improved isolation may be necessary.

FIG. 5A shows a prior art example providing a chip package structure 500 with such properties, namely by having a thermal interface material stack 512, 550, 552 between the chip and the outer package surface such as a stack of aluminum 512 and , for example, epoxy films 550, 552, wherein the first expoxy film 550 may be a fully cured epoxy film (also referred to as C-stage), and the second epoxy film 552 may be only partially cured.(also referred to as B-stage), which may be useful for softening the second epoxy film 552 and for attaching the chip 104 and/or a leadframe 560 to the softened epoxy film 552.

However, as illustrated in FIG. 5B showing the chip package structure 500 of FIG. 5A, a problem that may arise is that in particular large chip package structures 500 may be subject to high stress inside the package structure 500, which may cause an unwanted delamination (indicated by thick bars and arrows) between an encapsulation material 562 (for example, a molding compound, EMC) and the various layers of the TIM stack (aluminum plate 512, epoxy sheets 552, 554).

### SUMMARY

A chip package structure is provided. The chip package may include a chip, an encapsulation material, and an exposed pad that is electrically conductively connected to the chip, a layer of a porous or dendrite-comprising adhesion promoter on a surface of the exposed pad, and a thermal interface material that is attached to the exposed pad by the layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

each of FIGS. 1A to 1E shows a schematic cross-sectional view of a chip package structure in accordance with various embodiments;

each of FIG. 2A and FIG. 2B illustrates a method of forming a chip package structure in accordance with various embodiments;

FIG. 3 shows a schematic cross-sectional view of a chip package structure in accordance with various embodiments;

FIG. 4 shows a flow diagram of a method of forming a chip package structure in accordance with various embodiments;

FIG. 5A illustrates a method of forming a chip package structure according to a prior art, and FIG. 5B shows a resulting chip package structure;

FIG. 6A illustrates a method of forming a chip package structure according to various embodiments;

each of FIG. 6B and 6C shows a schematic cross-sectional view of a chip package structure in accordance with various embodiments; and

FIG. 7 shows a flow diagram of a method of forming a chip package structure in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

Various aspects of the disclosure are provided for devices, and various aspects of the disclosure are provided for methods. It will be understood that basic properties of the devices also hold for the methods and vice versa. Therefore, for sake of brevity, duplicate description of such properties may have been omitted.

To ensure a good heatflow between the interfaces, and optionally a reliable electrical isolation, connections between the chip package and a heat sink need to be robust over a lifetime.

In various embodiments, a porous or dendritic adhesion promoter may be provided between the chip package (e.g., an exposed (e.g., metal) pad) and the thermal interface material. The adhesion promoter may in various embodiments be additionally arranged between packaging material of the chip package and the thermal interface material.

In the case of the adhesion promoter having the porous structure, the adhesion promoter may have cavities, into which the thermal interface material may flow when it is arranged in pasteous or liquid form, before it solidifes.

In the case of the adhesion promoter having the dendritic structure, the (initially liquid or pasteous) thermal interface material may enlose the dendritic structure of the adhesion promoter before it solidifies.

In various embodiments, the adhesion promoter may be provided with both, pores and dendrites.

The structure of the adhesion promoter (e.g. as described above, e.g. with pores and/or dendrites) may lead to a mechanical interlock (also described as mechanical anchoring) between the adhesion promoter and the thermal interface material

The adhesion promoter may additionally have an excellent adhesion to the chip package, for example to the exposed (e.g. metal) pad, and/or to the packaging material, for example a molding material as known in the art. For example, the adhesion promoter may have a CTE that is closer to the CTE of the chip package material(s) that it is formed on than the thermal interface material. In other words, |CTE_{exposed pad}−CTE_{adhesion promoted}|<|CTE_{exposed pad}−CTE_{thermal interface material}| and/or |CTE_{packaging material}−CTE_{adhesion promoted}|<|CTE_{packaging material}−CTE_{thermal interface material}|. Alternatively or additionally, a chemical and/or physical adhesion of the first adhesion pair (exposed pad—adhesion promoter) and/or of the second adhesion pair (packaging material—adhesion promoter), may be higher than between the prior art adhesion pairs (exposed pad—thermal interface material; packaging material—thermal interface material).

In the prior art (without using the dendritic/porous adhesion promoter), the long-term stability of the high thermal conductivity may be critical (e.g., in danger) due to the above mentioned CTE mismatch, and/or due to other adhesion limiting factors.

In various embodiments, the porous or dendrite-comprising adhesion promoters may on the one hand be able to compensate the CTE mismatch, and may on the other hand be temperature stable and not show any degradation.

In various embodiments. the chip package structure may include the dendrite comprising adhesion promoter in combination with a, for example compression molded, TIM layer.

The dendrite-comprising adhesion promoter may for example be an inorganic adhesion promoter, for example as formed by a so-called A2 plating process. The A2 plating process may use a commercially available plating bath, which may for example be used for forming a dendritic adhesion promoter that includes zirconium and chromium, or, as a so-called Cr6-free A2, a dendritic combination of a zinc-vanadium layer and a zinc-vanadium oxide layer.

An atomic layer deposition (ALD) may be applied on electrically conductive and/or non-conductive surfaces. In other words, using ALD, the adhesion promoter may in various embodiments be deposited on conductive and/or non conductive materials, therefore the dendritic structure may in various embodiments be despoitend on a whole (e.g. back) side of a chip package structure, wherein the side may include both conductive (e.g. metal) and non-conductive (e.g. polymer) surfaces.

In various embodiments, the porous adhesion promoter may be formed by hydrothermally treated aluminum oxide layer.

In various embodiments, the porous or dendrite-comprising adhesion promoter may be formed as a layer of nanoparticles, which may be fromed using spark ablation. The nanoparticles may for example include or consist of a conductive or semiconductive material, for example a metal, metal alloy or semiconductor material. In various embodiments, the layer of nanoparticles with the cavities/dendrites that forms the adhesion promoter may for example include or consist of the metal that forms the surface of the exposed pad.

As yet another example, a silica aerogel may in various embodiments be used as the adhesion promoter.

After the deposition of the porous or dendritic adhesion promoter, the thermal interface material (which may be an electrical insulation layer) may be formed on, e.g. molded onto, the adhesion promoter. The thermal interface material may in various embodiments be arranged by compression molding or other molding processes like transfer moldig, or for example by printing or laminating. The thermal interface material (e.g., electrical insulation material) may for example be silicone or an epoxy material, or any other kind of polymer that is provided in a fluid state to be able to fill up the dendritic or porous shell-like structure of the adhesion promoter layer.

Exemplary materials for the thermal interface material may include or consist of thermoplasts like polyethylene, polyvinylchloride, polytetraflourethylene, polyesters, polycarbonates, or polypropylen, of duromers like polyurethanes, melamin-resin, or epoxy-resin, or of elastomers, like silicone, ethylene-propylen-copolymer.

In various embodiments, these materials may be highly filled with ceramic fillers such as Al₂O₃, BN, AlN, MgO.

For a so-called “advanced isolation”, in other words, a high-quality electrical isolation, a layer that is very robust with respect to scratches may be required. Therefore, relatively hard materials (e.g., as compared with materials that are used for chip packages with less stringent requirements on scratch resistance) may be used, for example as the packaging material, e.g. the mold material. The above described embodiments that include the porous/dendritic adhesion promoter may be particularly well suited for avoiding a risk of delamination.

Each of FIGS. 1A to 1E shows a schematic cross-sectional view of a chip package structure 100 in accordance with various embodiments, and each of FIG. 2A and FIG. 2B illustrates a method of forming a chip package structure 100 in accordance with various embodiments.

The chip package 100 may include a chip 104, an encapsulation material 106, and an exposed pad 108 that is electrically conductively connected to the chip 104. The chip 104, the encapsulation, and the exposed pad 108 may together form the chip package 102. The chip package 102 may in various embodiments include further components like for example eletrical leads (for example for contacting chip contacts arranged on a side of the chip 104 opposite the exposed pad 108), additional layers, for example between the chip 104 and the encapsulation 106, and/or at an interface between the exposed pad 108 and the encapsulation 106, an additional chip, etc.

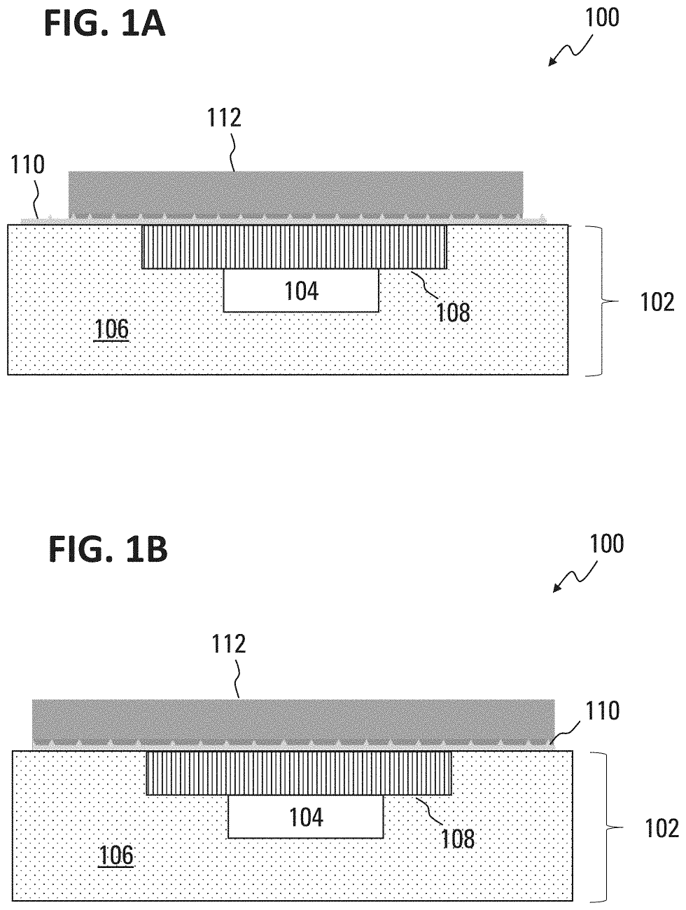

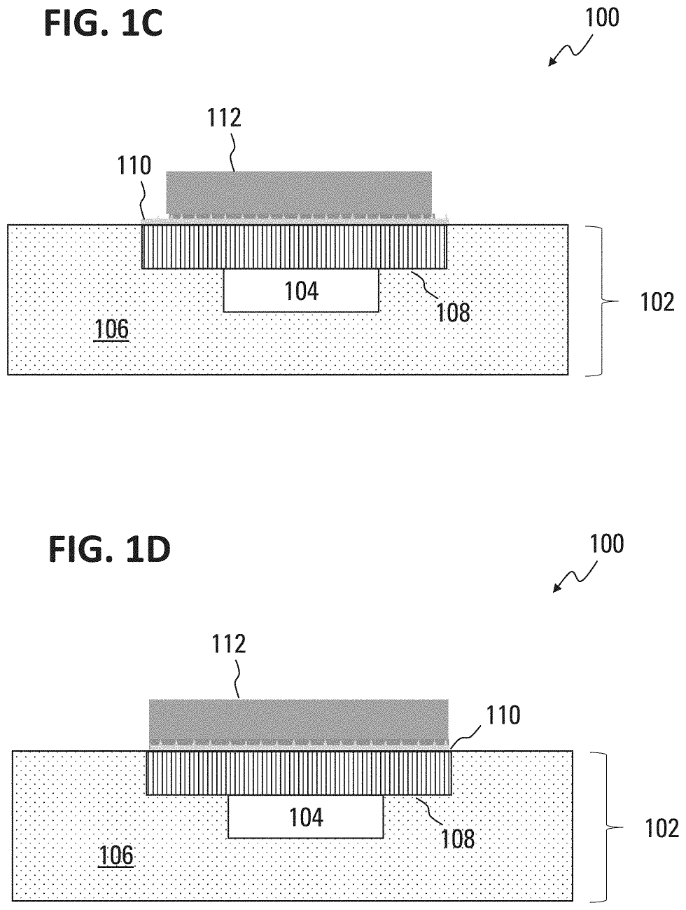

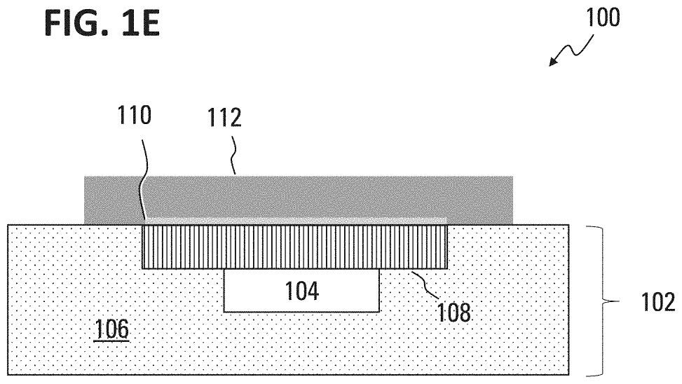

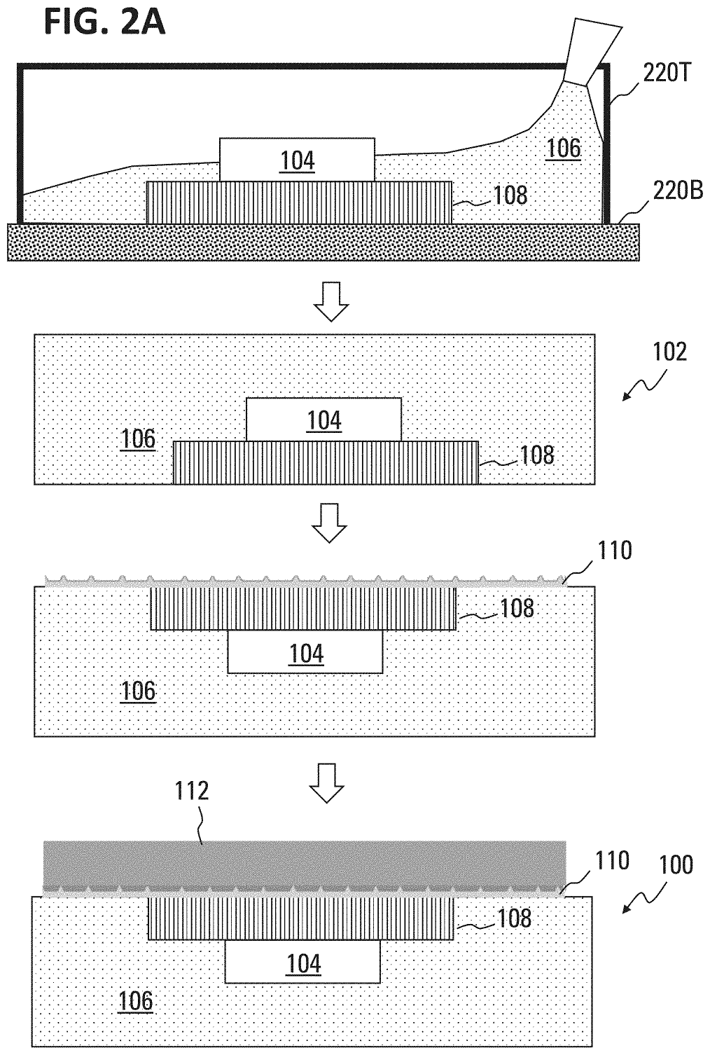

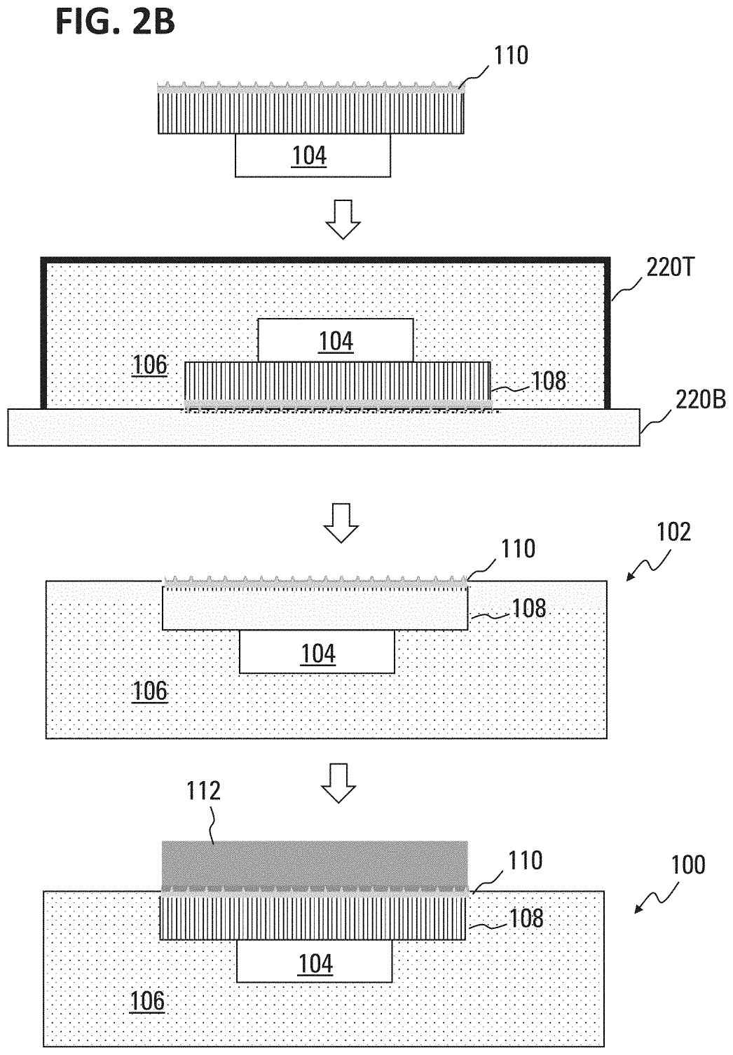

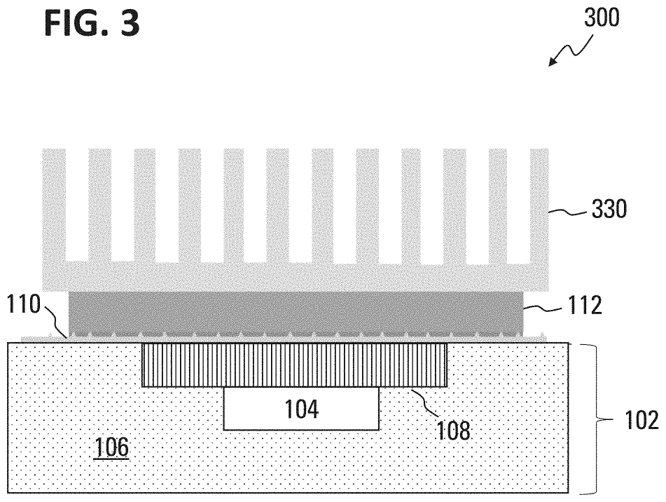

The chip 104 may in various embodiments be or include any suitable type of semiconductor chip that is typically included in a chip package 102, in particular a power circuit element like a power transistor or the like that benefits particularly from the good cooling enabled by a firmly attached thermal interface material 112 (and, as shown in FIG. 3, the heat sink 330 attached to the thermal interface material 112).

The exposed pad 108 may in various embodiments be an exposed portion of a leadframe to which the chip 104 is attached, or a chip contact pad (e.g. a drain contact covering for example a whole main surface of the chip 104), a clip electrically contacting the chip 104, or the like. The exposed pad 108 may include or consist of an electrically conductive material, for example a metal, for example a metal that is typically used for electrically contacting a chip, for example copper or a copper alloy. The exposed pad 108 may in various embodiments include a layer stack of different metals, or a metal body with one or more metal layers formed thereon.

The exposed pad 108 may have been left exposed during the arranging of the encapsulation material 106 (see FIG. 2A and 2B, which show an exemplary molding process involving a top mold 220T and a bottom mold 220B, wherein the bottom mold is configured to prevent the encapsulation material 106 from reaching the exposed pad 108), or may have been freed from the encapsulation material 106 and/or from a protective layer after the encapsulation process (not shown).

The encapsulation material 106 may be or include any suitable type of encapsulation material typically used in a chip package 102, for example a polymer material, e.g. a mold material.

The chip package structure 100 may in various embodiments include a layer of a porous or dendrite-comprising adhesion promoter 110 (also referred to as porous/dendritic layer, porous/dendritic adhesion promoter, adhesion promoter or simply layer, if it is clear from the context that the porous/dendritic layer is referred to) on a surface of the exposed pad 108. The adhesion promoter 110 may be in direct contact with the exposed pad 108. The adhesion promoter 110 may for example be formed directly on the exposed pad 108.

In the case of the adhesion promoter 110 having the dendrites, the adhesion promoter 110 may for example be an inorganic adhesion promoter, for example an adhesion promoter formed by an A2 plating process, for exmaple including zirconium and chromium, or, as a so-called Cr6-free A2, a combination of a zinc-vanadium layer and a zinc-vanadium oxide layer that includes dendrites on its exposed surface, in other words on the surface facing away from the exposed pad 108. During the electroplating process, the electroplating conditions may be controlled, for example as known in the art, to allow or enforce the electroplated layer to grow with a dendritic structure, for example to a desired average thickness and/or surface roughness.

In the following, exemplary electrolyte components and electroplating conditions are described for the chromium-free A2 process.

The electroplating process may be used for forming the detrite-comprising adhesion promoter on electrically conductive surfaces, for example on the exposed metal pad.

The electrolyte may include sodium or potassiumsilicate, sodium- or potassium hydroxide, sodium- or potassium vanadate, and zincate (Na or K).

| | | Concentration of | |
|---|---|---|---|
| | | metal in electrolyte | Ranges |
| Species | Metal | [mole/l] V | [mole/l] |
| NaOH | NaOH | 0.2861 | 0.1-0.5 |
| Na₂O:SiO₂ (27% SiO₂) | Si | 0.0025 | 0.001-0.01 |
| K₃VO₄ | V(VII) | 0.0118 | 0.1-0.001 |
| ZnO | Zn | 0.0210 | 0.1-0.001 |

During the deposition, the current density of the direct current may be about 45 mA/cm². For a pulse plating, 228 mA/cm² peak current with pulse/dwell function of 10 ms on, 10 ms off may be used. The temperature may be in a range from about 30° C. to about 95° C. (with a target temperature of about 50° C., and the electrolyte flow may be in a range from about 2 to about 200 cm/s.

Using the electroplating, e.g. the A2 process, the nature of the process may cause the adhesion promoter 110 to be formed only on electrically conductive surfaces, for example only on the exposed pad 108, for example as shown in FIG. 1C, FIG. 1D, FIG. 1E, and FIG. 2B. The adhesion promoter 110 may be arranged before the encapsulation 106 is formed (see for example FIG. 2B), or after the encapsulation 106 is formed (see for example FIG. 2A).

In various embodiments (not shown), the exposed pad 108 may be the only surface facing the heat sink 330. In other words, an area of the encapsulation material 106 covering the exposed pad 108 (e.g., the leadframe) from the back side may match an area of the exposed pad 108 or be smaller than that.

In various embodiments, the adhesion promoter 110 may be limited to the exposed pad 108 by other techniques, for example by using masks for limiting the area in which the adhesion promoter 110 is formed to the exposed pad 108.

In various embodiments, the adhesion promoter 110 may be additionally arranged over, e.g. in contact with, the encapsulation material 106. In other words, the adhesion promoter 110 may extend from the exposed pad 108 onto the encapsulation materia 106. The encapsulation material 106 may in various embodiments be adjacent to the exposed pad 108. The exposed pad 108 and the encapsulation material 106 may in various embodiments form a common surface, in which the encapsulation material 106 may at least partially, e.g. fully, surround the exposed pad 108.

The adhesion promoter 110 may in various embodiments be arranged to cover at least a portion of the encapsulation material 106, see the exemplary embodiments shown in FIG. 1A, FIG. 1B and FIG. 2A. The adhesion promoter 110 may be arranged to fully or almost fully cover one of the main surfaces of the chip package 102, for example the surface that includes the exposed pad 108. In various embodiments, the adhesion promoter 110 may be arranged to cover only a portion of the main surface, for example extending over the edge of the exposed pad 108 towards an edge of the chip package 102 in at least one direction. The adhesion promoter 110 may in various embodiments be arranged to symmetrically extend, e.g. on all sides, over an edge or edges of the exposed pad 108 onto the encapsulation material 106.

For depositing a material that may adhere to both, the electrically conductive exposed pad 108 and the encapsulation material, e.g. as described above, an atomic layer deposition (ALD) or other suitable techniques that additionally allow forming a porous and/or dendritic structure may in various embodiments be used. In other words, using ALD, the adhesion promoter may in various embodiments be deposited on conductive and/or non conductive materials.

In various embodiments, the porous adhesion promoter may be formed by depositing aluminum oxide, e.g. in an ALD process, and by subjecting the layer to a hydrothermal treatment, thereby forming a rough/porous (boehmite) AlOOH layer, for example as described in DE 10 2018 118 544 A1.

In various embodiments, the porous or dendrite-comprising adhesion promoter may be formed as a layer of nanoparticles, which may be fromed using spark ablation of electrodes made from the material to be deposited as the nanoparticles. The nanoparticles may for example include or consist of a conductive or semiconductive material, for example a metal, metal alloy or semiconductor material. In various embodiments, the layer of nanoparticles with the cavities/dendrites that forms the adhesion promoter may for example include or consist of the metal that forms the surface of the exposed pad.

As yet another example, a silica aerogel may in various embodiments be used as the adhesion promoter.

The chip package structure 100 may in various embodiments include a thermal interface material 112 that is attached to the exposed pad 108 by the porous/dendritic layer 110.

The thermal interface material (TIM) 112 may be liquid or paste-like at the temperature of application when the thermal interface material 112 is arranged. Thereby, it may be ensured that the thermal interface material 112 may flow or be pressed into the pores or, more generally, cavities, of the adhesion promoter 110, or may arrange itself around the dendrites. After solidifying of the thermal interface material 112 (e.g., by thermosetting, UV irradiation, or the like), a firm interlock structure may be formed by the thermal interface material 112 and the adhesion promoter 110. The thermal interface material 112 may in various embodiments be arranged by a molding process, for example by compression molding or transfer moldig, or for example by printing, laminating or 3D printing.

The thermal interface material 112 may in various embodiments include or consists of a thermosetting resin, a silicone, epoxy, a rubber, epoxy-polyimid and/or a thermoplastic, or the like.

The thermal interface material 112 may extend all the way to the edge of the adhesion promoter 110. In other words, an area covered by the thermal interface material 112 may essentially or completely match the area covered by the adhesion promoter 110. See FIG. 1B, FIG. 1D, FIG. 2A and FIG. 2B for examplary embodiments.

In various embodiments, the thermal interface material 112 may not fully cover the adhesion promoter 110. Exemplary embodiments are shown in FIG. 1A and FIG. 1C.

A situation in which the thermal interface material 112 extends beyond the adhesion promoter 110 onto a surface of the encapsulation material 106 may in various embodiments be avoided, at least in the case where the adhesion promoter at least partially covers the encapsulation material, because an area where the thermal interface material 112 directly contacts the encapsulation material, and an adhesion between the thermal interface material 112 and the encapsulation material 106 is reduced, could otherwise possibly form a starting point for a peeling of the thermal interface material 112 also over the exposed pad 108.

In a case where a good adhesion is ensured also in case of a direct contact between the thermal interface material 112 and the encapsulation material, for example by specifically selected materials, the thermal interface material 112 may be allowed to form a direct contact with the encapsulation material 106. A corresponding exemplary embodiment of such a chip package structure 100, in which the adhesion promoter 110 is formed only on the exposed pad 108, the thermal interface material 112 is attached to the exposed pad 108 by the adhesion promoter 110, and the thermal interface material 112 is formed to extend onto the encapsulation material 106 (on which no adhesion promoter 110 is formed), is shown in FIG. 1E.

In various embodiments, the thermal interface material 112 may form an interface to a heat sink 330, typically a structure with excellent thermal conductivity (e.g. a metal) and a large surface, which may for example be cooled by a coolant, e.g. air or water. FIG. 3 shows an exemplary embodiment of a chip package system 300 that may include any of the chip package structures 100 described above, and may further include a heat sink 330 that is directly attached (in particular, with a thermally conductive connection) to the thermal interface material. The heat sink 330 may be mounted to the thermal interface material 112 essentially as known in the art.

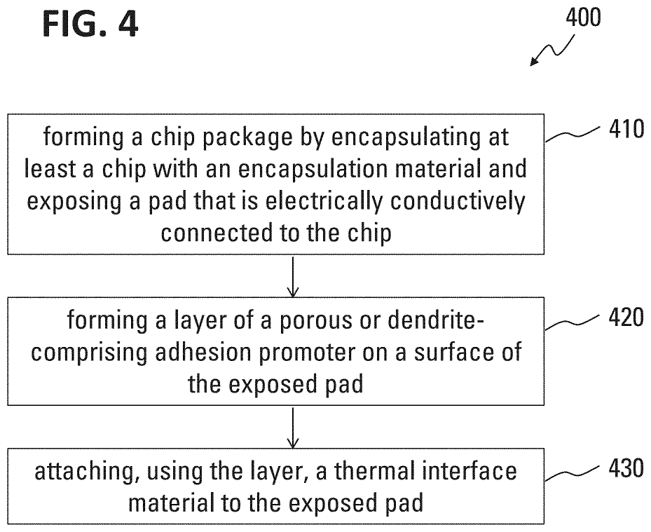

FIG. 4 shows a flow diagram 400 of a method of forming a chip package structure in accordance with various embodiments.

The method may include forming a chip package by encapsulating at least a chip with an encapsulation material and exposing a pad that is electrically conductively connected to the chip (410), forming a layer of a porous or dendrite-comprising adhesion promoter on a surface of the exposed pad (420), and attaching, using the layer, a thermal interface material to the exposed pad (430).

In various embodiments, the thermal interface material 112, 512 may include or consist of a metal, and the porous or dendrite-comprising adhesion promoter 110 may be formed on a surface of the thermal interface material 112, 512, for example on a surface that is internal to the chip package structure 100, 300, 600, and/or on a surface that is exposed by the chip package structure 100, 600. This may apply to any of the above described embodiments, unless it is explicitly described or clear from the context that a non-metallic thermal interface material 112, 512 is described as the only option.

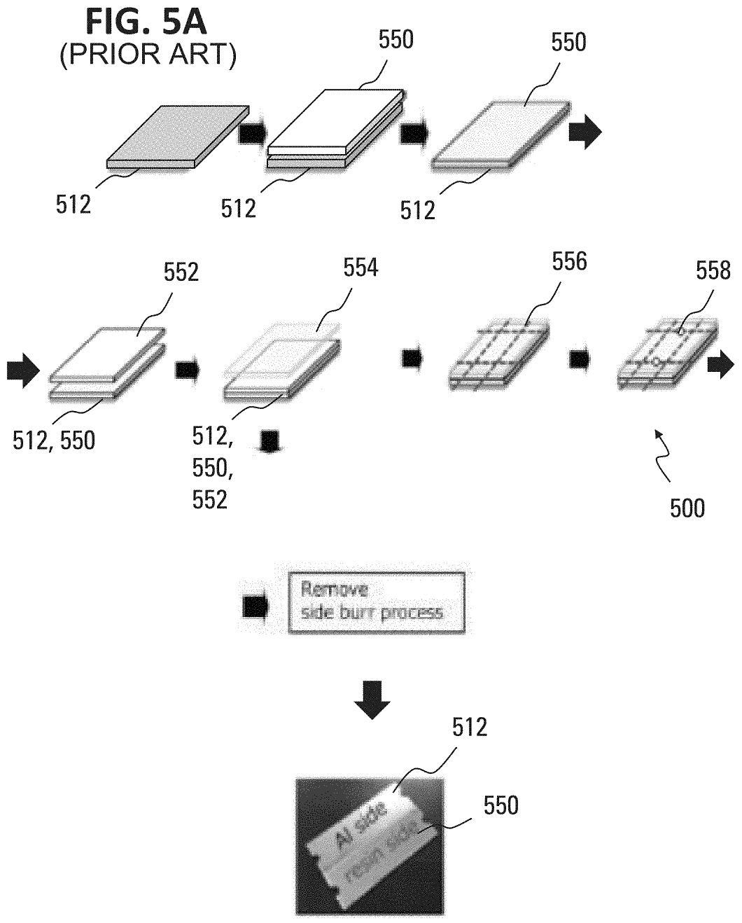

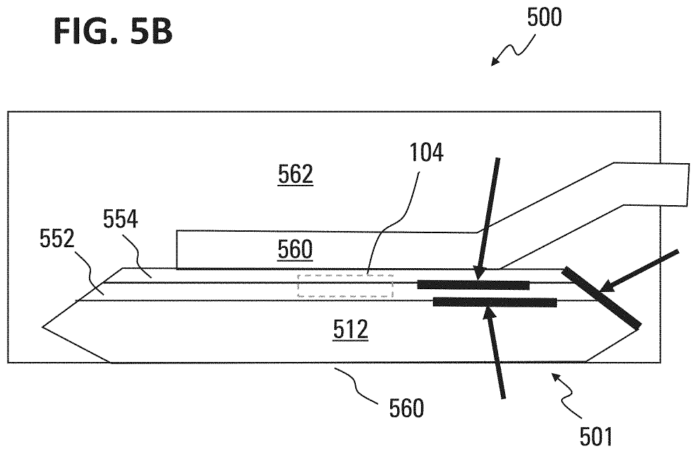

FIG. 5A, as described above, illustrates a method of forming a chip package structure 500 according to a prior art, and FIG. 5B illustrates a cross-sectional view of a resulting chip package structure 500.

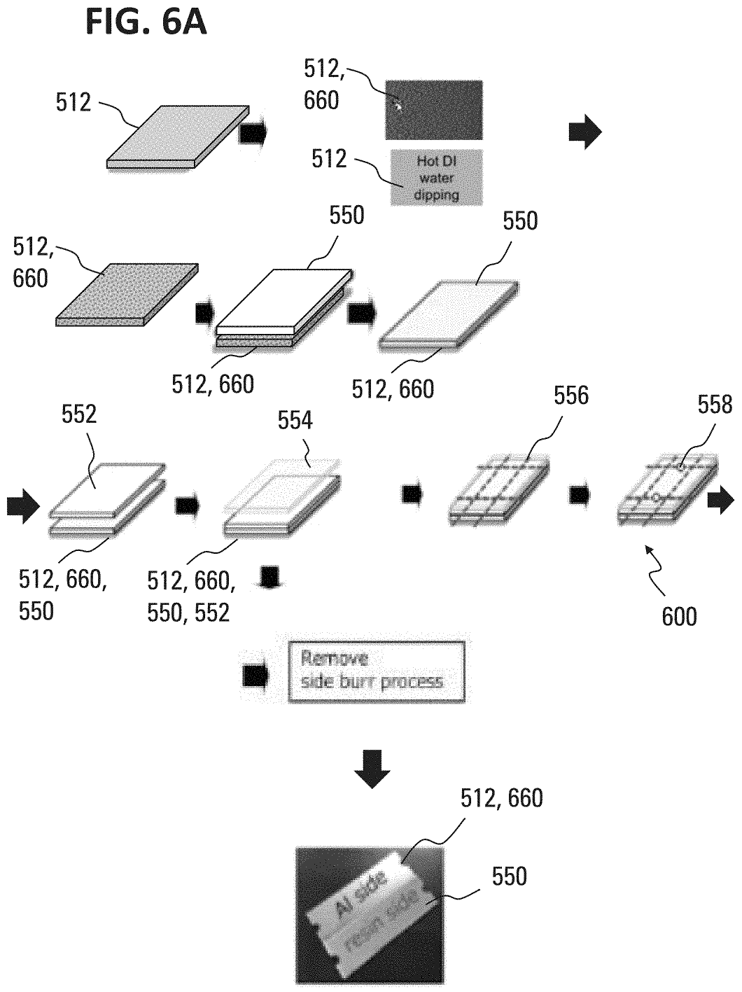

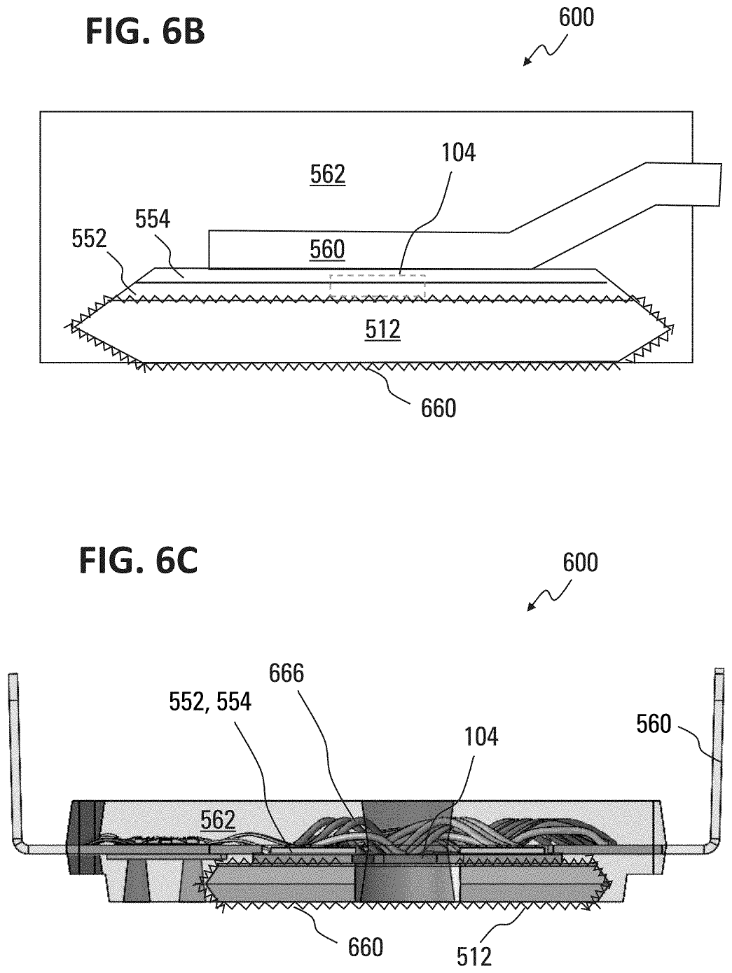

FIG. 6A illustrates how the method of FIG. 5A may be modified in order to provide the chip package structure 600 in accordance with various embodiments, and each of FIG. 6B and FIG. 6C shows a schematic cross-sectional view of a chip package structure 600 in accordance with various embodiments, which may optionally include the chip package structure 600 of FIG. 6A. In FIG. 6B, the chip 104 may be arranged outside the plane of the cross section, and is therefore shown only as a dashed line, but FIG. 6C includes the chip 104 and bonding wires 666 electrically connecting the chip 104 to a leadframe 560.

In various embodiments, the chip package structure 600 may include a chip package including a chip 104 and an encapsulation material 562, a thermal interface 512 that includes or consists of a metal and is thermally connected to the chip package, for example to the chip 104 and/or to encapsulation material 562 and/or to an interface material 552, 554, and a layer 660 of a porous or dendrite-including adhesion promoter 660 on a surface of the thermal interface 512.

In other words, in various embodiments, the layer of the porous or dendrite-comprising adhesion promoter 110 may be arranged, alternatively or in addition to the exposed pad, on the thermal interface 512, which may include or consist of a metal.

For ease of reference, the adhesion promoter 660 on the thermal interface 512 is provided with its own reference number 660, even though, at least in various embodiments, the materials of the adhesion promoter 660 and of the adhesion promoter 110 may be the same and they may even be applied/formed during a common process, for example after the thermal interface 512 is attached to the exposed pad 108.

In various embodiments, the porous or dendrite-comprising adhesion promoter 110 on the exposed pad 108 may differ from the porous or dendrite-comprising adhesion promoter 660 on the thermal interface 512. This may for example be useful in a case where the exposed pad 108 and the thermal interface 512 are provided with their respective porous or dendrite-comprising adhesion promoter 110 and 660, respectively, before they are joined.

The surface of the thermal interface 512 on which the porous or dendrite-including adhesion promoter 660 is formed may include any of the surfaces of the thermal interface 512, for example the surface(s) forming the interface to the chip package, and/or the surface exposed from the chip package.

In various embodiments, an adhesion between the thermal interface 512, e.g. an aluminum plate/block, and the structures it is attached to, e.g. the encapsulation material 562, e.g. a molding compound, can be improved by roughening the surface of the thermal interface 512 (e.g., the aluminum plate/block) by dipping into hot deionized (DI) water. Thereby, a naturally formed or deliberately applied aluminum oxide (Al₂O₃) layer on the thermal interface 512 may be converted to a dendrite-comprising boehmite (AlOOH) layer with increased adhesive properties. Experiments have shown that the dendrite-comprising boehmite (AlOOH) layer on the aluminum surface increases the adhesion even after stress testing. The process itself is easy and cheap. The thermal interface 512 may for example be dipped into the hot DI water for about ten minutes. This process may be performed in parallel on a large number of thermal interfaces 512.

Alternatively, other porous or dendrite-comprising adhesion promoters 110 as described above may be used for the adhesion promoter 660, and may be formed as described there.

In various embodiments, as illustrated in FIG. 6A, the porous or dendrite-comprising adhesion promoter 110 may be formed on the thermal interface 512 before the thermal interface 512 is attached to any other element of the chip package structure 600. Thereby, it may be ensured that all interfaces between the thermal interface 512 and other components of the chip package structure 600, e.g. the encapsulation material 562, the chip 104, the interface material 550 (in various embodiments, it may be sufficient to provide just one interface material 550, rather than the combination of C-stage material and B-stage material as used in the prior art), a heat sink 330 similar to the embodiment shown in FIG. 3, etc.

In various embodiments (examples of which are shown in FIG. 6A to 6C), the thermal interface 512 may have a shape with an hexagonal cross-section through its main surfaces. In other words, the thermal interface 512 may have, as shown in FIG. 6A to 6C, a shape with large opposing main surfaces and a V-shaped edge joining the surfaces, with the bottom of the V pointing outward. This shape of the thermal interface 512 may combine two advantages over other shapes of the thermal interface 512, e.g. over a thermal interface 512 with a rectangular cross-section, in that the thermal interface 512 with the hexagonal cross-section may be more securely anchored in the encapsulation material 562, and in that it is more easily manufacturable (e.g., by simply forming two opposing V-shaped grooves in a plate, as illustrated in FIG. 6A) than a thermal interface 512 that is securely anchorable by providing it with a shape that has a stepped cross-section (to be arranged with the broader portion of the thermal interface 512 towards an inside of the chip package 600). In various embodiments, the thermal interface 512 may have any suitable shape, e.g. as known in the art.

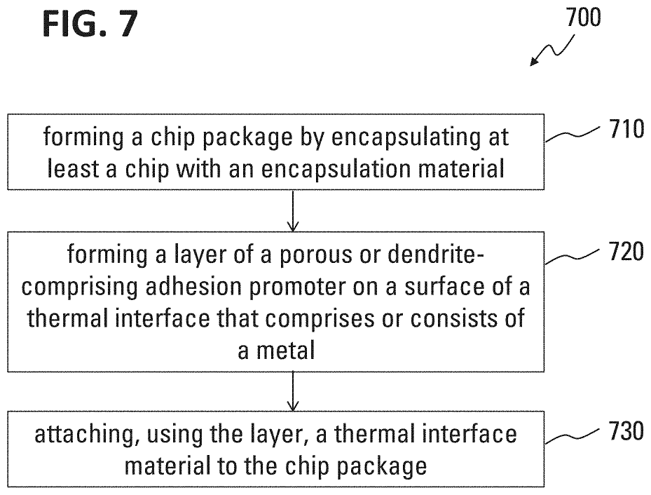

FIG. 7 shows a flow diagram 700 of a method of forming a chip package structure in accordance with various embodiments.

The method may include forming a chip package by encapsulating at least a chip with an encapsulation material (710), forming a layer of a porous or dendrite-including adhesion promoter on a surface of a thermal interface (720), and attaching, using the adhesion promoter, the thermal interface to the chip package (730).

Various examples will be illustrated in the following:

Example 1 is a chip package structure. The chip package may include a chip, an encapsulation material, and an exposed pad that is electrically conductively connected to the chip, a layer of a porous or dendrite-comprising adhesion promoter on a surface of the exposed pad, and a thermal interface material that is attached to the exposed pad by the layer.

In Example 2, the subject-matter of Example 1 may optionally include that the thermal interface material is an organic material.

In Example 3, the subject-matter of Example 1 may optionally include that the thermal interface material is an inorganic material.

In Example 4, the subject-matter of any of Examples 1 to 3 may optionally include that the adhesion promoter is an organic adhesion promoter.

In Example 5, the subject-matter of any of Examples 1 to 3 may optionally include that the adhesion promoter is an inorganic adhesion promoter.

In Example 6, the subject-matter of Example 5 may optionally include that the inorganic adhesion promoter includes aluminum oxide.

In Example 7, the subject-matter of Example 6 may optionally include that the inorganic adhesion promoter includes hydrothermally treated aluminum oxide.

In Example 8, the subject-matter of Example 5 may optionally include that the inorganic adhesion promoter includes a material that is deposited by an A2 process and/or by atomic layer deposition (ALD) and/or a nanoparticle layer obtained by spark ablation.

In Example 9, the subject-matter of any of Examples 1 to 8 may optionally include that the thermal interface material is a compression molded, printed, laminated, molded, 3D-printed and/or transfer molded thermal interface material.

In Example 10, the subject-matter of any of Examples 1 to 9 may optionally include that the thermal interface material includes or consists of an a thermosetting resin, a silicone, a rubber, and/or a thermoplastic.

In Example 11, the subject-matter of Example 10 may optionally include that the resin is an epoxy resin.

In Example 12, the subject-matter of any of Examples 1 to 11 may optionally include that the adhesion promoter extends beyond the exposed pad to at least partially cover a surface of the encapsulation material.

In Example 13, the subject-matter of Example 12 may optionally include that the thermal interface material extends in contact with the adhesion promoter beyond the exposed pad to at least partially cover the encapsulation material.

In Example 14, the subject-matter of any of Examples 1 to 13 may optionally include that the exposed pad is a chip contact, part of a redistribution structure, or a clip.

Example 15 is a method of forming a chip package structure. The method may include forming a chip package by encapsulating at least a chip with an encapsulation material and exposing a pad that is electrically conductively connected to the chip, forming a layer of a porous or dendrite-comprising adhesion promoter on a surface of the exposed pad, and attaching, using the layer, a thermal interface material to the exposed pad.

In Example 16, the subject-matter of Example 15 may optionally include that the thermal interface material is an organic material.

In Example 17, the subject-matter of Example 15 may optionally include that the thermal interface material is an inorganic material.

In Example 18, the subject-matter of any of Examples 15 to 17 may optionally include that the adhesion promoter is an organic adhesion promoter.

In Example 19, the subject-matter of any of Examples 15 to 17 may optionally include that the adhesion promoter is an inorganic adhesion promoter.

In Example 20, the subject-matter of Example 19 may optionally include that the inorganic adhesion promoter includes aluminum oxide.

In Example 21, the subject-matter of Example 20 may optionally include that the forming the layer of the inorganic adhesion promoter includes hydrothermally treating aluminum oxide.

In Example 22, the subject-matter of Example 19 may optionally include that the forming the layer of the inorganic adhesion promoter includes depositing the layer by an A2 process and/or by atomic layer deposition (ALD) and/or forming a nanoparticle layer by spark ablation.

In Example 23, the subject-matter of any of Examples 15 to 22 may optionally include that the attaching the thermal interface material includes at least one of a group of processes, the group including compression molding, printing, laminating, molding, and transfer molding.

In Example 24, the subject-matter of any of Examples 15 to 23 may optionally include that the thermal interface material includes or consists of an a thermosetting resin, a silicone, a rubber, and/or a thermoplastic.

In Example 25, the subject-matter of Example 24 may optionally include that the resin is an epoxy resin.

In Example 26, the subject-matter of any of Examples 15 to 25 may optionally include that the adhesion promoter extends beyond the exposed pad to at least partially cover a surface of the encapsulation material.

In Example 27, the subject-matter of Example 26 may optionally include that the thermal interface material extends in contact with the adhesion promoter beyond the exposed pad to at least partially cover the encapsulation material.

In Example 28, the subject-matter of any of Examples 15 to 27 may optionally include that the exposed pad is a chip contact, part of a redistribution structure, or a clip.

In Example 29, the subject-matter of any of Examples 15 to 25 may optionally include that the adhesion promoter is formed before the encapsulating of the chip.

In Example 30, the subject-matter of any of Examples 15 to 28 may optionally include that in the adhesion promoter is formed after the encapsulating of the chip.

In Example 31, the chip package structure of any of Examples 1, 3 to 8, or 12 to 14 may optionally include that the thermal interface material includes or consists of a metal, the chip package structure further including a layer of a porous or dendrite-comprising adhesion promoter on a surface of the thermal interface.

In Example 32, the chip package structure of Example 31 may optionally include that the adhesion promoter on the surface of the exposed pad and the adhesion promoter on the surface of the thermal interface include or consist of the same material, which is optionally formed during a common process.

Example 33 is a chip package structure. The chip package structure may include a chip package including a chip and an encapsulation material, a thermal interface that includes or consists of a metal and is thermally connected to the chip package, and a layer of a porous or dendrite-including adhesion promoter on a surface of the thermal interface.

In Example 34, the chip package structure of Example 33 may optionally include that the adhesion promoter is an inorganic adhesion promoter.

In Example 35, the chip package structure of Example 34 may optionally include that the inorganic adhesion promoter includes aluminum oxide.

In Example 36, the chip package structure of Example 34 or 35 may optionally include that the inorganic adhesion promoter include hydrothermally treated aluminum oxide.

In Example 37, the chip package structure of Example 33 may optionally include that the adhesion promoter is an organic adhesion promoter.

In Example 38, the chip package structure of any of Examples 33 to 37 may optionally include that the adhesion promoter is arranged between the thermal interface and the chip and/or between the thermal interface and the encapsulation material.

In Example 39, the chip package structure of any of Examples 33 to 38 may optionally include that the metal of the thermal interface material is at least one of a group of metals, the group including aluminum and copper.

In Example 40, the chip package structure of any of Examples 33 to 39 may optionally include that the thermal interface is partially integrated in the encapsulation material.

In Example 41, the chip package structure of any of Examples 33 to 40 may optionally include that the thermal interface has a shape with an hexagonal cross-section through its main surfaces.

Example 42 is a method of forming a chip package structure. The method may include forming a chip package by encapsulating at least a chip with an encapsulation material, forming a layer of a porous or dendrite-including adhesion promoter on a surface of a thermal interface, and attaching, using the adhesion promoter, the thermal interface to the chip package.

In Example 43, the method of Example 42 may optionally include that the adhesion promoter is an inorganic adhesion promoter.

In Example 44, the method of Example 43 may optionally include that the inorganic adhesion promoter includes aluminum oxide.

In Example 45, the method of Example 43 or 44 may optionally include that the inorganic adhesion promoter comprises hydrothermally treated aluminum oxide.

In Example 46, the method of Example 42 may optionally include that the adhesion promoter is an organic adhesion promoter.

In Example 47, the method of any of Examples 42 to 46 may optionally include that the layer of the porous or dendrite-including adhesion promoter is formed on the surface of the thermal interface before the chip package is attached to the thermal interface.

In Example 48, the method of any of Examples 42 to 46 may optionally include that the the layer of the porous or dendrite-including adhesion promoter is formed on the surface of the thermal interface after the chip is attached to the thermal interface and before the encapsulating of the chip and at least a portion of the thermal interface by the encapsulation material.

In Example 49, the method of Example 48 may optionally include that the chip package further includes a leadframe electrically conductively connected to the chip, and that the adhesion promoter is additionally formed on the leadframe during the forming of the adhesion promoter on the thermal interface, and that the encapsulating at least partially encapsulates the leadframe.

Example 50 is a chip package system. The chip package system may include a chip package structure of any of Examples 1 to 14 or 31 to 41, and a heat sink attached to the thermal interface material.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A chip package structure, comprising:
a chip package comprising a chip, an encapsulation material, and an exposed pad that is electrically conductively connected to the chip;
a layer of a porous or dendrite-comprising adhesion promoter on a surface of the exposed pad; and
a thermal interface material that is attached to the exposed pad by the layer.

2. The chip package structure of claim 1,
wherein the thermal interface material is an organic material.

3. The chip package structure of claim 1,
wherein the thermal interface material is an inorganic material.

4. The chip package structure of claim 1,
wherein the adhesion promoter is an organic adhesion promoter.

5. The chip package structure of claim 1,
wherein the adhesion promoter is an inorganic adhesion promoter.

6. The chip package structure of claim 5,
wherein the inorganic adhesion promoter comprises aluminum oxide.

7. The chip package structure of claim 6,
wherein the inorganic adhesion promoter comprises hydrothermally treated aluminum oxide.

8. The chip package structure of claim 5,
wherein the inorganic adhesion promoter includes a material that is deposited by an A2 process and/or by atomic layer deposition (ALD) and/or a nanoparticle layer obtained by spark ablation.

9. The chip package structure of claim 1,
wherein the thermal interface material comprises or consists of a thermosetting resin, a silicone, an epoxy, a rubber, an epoxy-polyimid, and/or a thermoplastic.

10. The chip package structure of claim 1,
wherein the adhesion promoter extends beyond the exposed pad to at least partially cover a surface of the encapsulation material.

11. The chip package structure of claim 10,
wherein the thermal interface material extends in contact with the adhesion promoter beyond the exposed pad to at least partially cover the encapsulation material.

12. The chip package structure of claim 1,
wherein the exposed pad is a chip contact, part of a redistribution structure, or a clip.

13. The chip package structure of claim 1,
wherein the thermal interface material comprises or consists of a metal,
the chip package structure further comprising:
a layer of a porous or dendrite-comprising adhesion promoter on a surface of the thermal interface.

14. The chip package structure of claim 13,
wherein the adhesion promoter on the surface of the exposed pad and the adhesion promoter on the surface of the thermal interface include or consist of the same material, which is optionally formed during a common process.

15. A chip package structure, comprising:
a chip package comprising a chip and an encapsulation material; and
a thermal interface that comprises or consists of a metal and is thermally connected to the chip package; and
a layer of a porous or dendrite-comprising adhesion promoter on a surface of the thermal interface.

16. The chip package structure of claim 15,
wherein the adhesion promoter is an inorganic adhesion promoter.

17. The chip package structure of claim 16,
wherein the inorganic adhesion promoter comprises aluminum oxide.

18. The chip package structure of claim 16,
wherein the inorganic adhesion promoter comprises hydrothermally treated aluminum oxide.

19. The chip package structure of claim 15,
wherein the adhesion promoter is an organic adhesion promoter.

20. The chip package structure of claim 15,
wherein the adhesion promoter is arranged between the thermal interface and the chip and/or between the thermal interface and the encapsulation material.

21. The chip package structure of claim 15,
wherein the metal of the thermal interface material is at least one of a group of metals, the group comprising:
aluminum; and
copper.

22. The chip package structure of claim 15,
wherein the thermal interface is partially integrated in the encapsulation material.

23. The chip package structure of claim 15,
wherein the thermal interface has a shape with an hexagonal cross-section through its main surfaces.

24. A chip package system, comprising:
a chip package structure of claim 1; and
a heat sink attached to the thermal interface material.
